(19) United States
(12) Patent Application Publication
(10) Pub. No.: US 2013/0125964 A1
(43) Pub. Date: May 23, 2013

(54) SOLAR CELL AND MANUFACTURING METHOD THEREOF

(71) Applicants: Chan-Bin MO, Yongin-si (KR); Doo-Youl LEE, Yongin-si (KR); Young-Jin KIM, Yongin-si (KR); Min-Seok OH, Yongin-si (KR); Sung-Chan PARK, Yongin-si (KR); Yun-Seok LEE, Yongin-si (KR); Nam-Kyu Song, Yongin-si (KR); Dong-Seop KIM, Yongin-si (KR); Min-Sung KIM, Yongin-si (KR); Cho-Young LEE, Yongin-si (KR); Young-su KIM, Yongin-si (KR); Young-Sang PARK, Yongin-si (KR)

(72) Inventors: Chan-Bin MO, Yongin-si (KR); Doo-Youl LEE, Yongin-si (KR); Young-Jin KIM, Yongin-si (KR); Min-Seok OH, Yongin-si (KR); Sung-Chan PARK, Yongin-si (KR); Yun-Seok LEE, Yongin-si (KR); Nam-Kyu Song, Yongin-si (KR); Dong-Seop KIM, Yongin-si (KR); Min-Sung KIM, Yongin-si (KR); Cho-Young LEE, Yongin-si (KR); Young-su KIM, Yongin-si (KR); Young-Sang PARK, Yongin-si (KR)

(21) Appl. No.: 13/569,217

(22) Filed: Aug. 8, 2012

(30) Foreign Application Priority Data
Nov. 18, 2011 (KR) 10-2011-0121045

(51) Int. Cl. H01L 31/0224; H01L 31/18

(52) U.S. Cl. 136/255; 438/72; 257/E31.124

(57) ABSTRACT

A solar cell including a crystalline semiconductor substrate having a first conductive type; a first doping layer on a front surface of the substrate and being doped with a first conductive type impurity; a front surface antireflection film on the front surface of the substrate; a back surface antireflection film on a back surface of the substrate; an intrinsic semiconductor layer, an emitter, and a first auxiliary electrode stacked on the back surface antireflection film and the substrate; a second doping layer on the back surface of the substrate and being doped with the first impurity; an insulating film on the substrate and including an opening overlying the second doping layer; a second auxiliary electrode in the opening and overlying the second doping layer; a first electrode on the first auxiliary electrode; and a second electrode on the second auxiliary electrode and being separated from the first electrode.

### BACKGROUND

1. Field

Embodiments relate to a solar cell and a manufacturing method thereof.

2. Description of the Related Art

In a solar cell, when an electrode (electrically connected to an emitter and a substrate) is positioned on a light, e.g., sunlight, incidence plane of the solar cell, the electrode may be positioned on the emitter such that a light incidence area may be reduced and the solar cell's efficiency may be deteriorated.

In order to increase a light incidence area, a back contact solar cell (in which electrodes for collecting electrons and holes are positioned on a back surface of a substrate) has been considered.

The above information disclosed in this Background section is only for enhancement of understanding of the background of the described technology and therefore it may contain information that does not form the prior art that is already known in this country to a person of ordinary skill in the art.

### SUMMARY

Embodiments are directed to a solar cell and a manufacturing method thereof.

The embodiments may be realized by providing a solar cell including a crystalline semiconductor substrate having a first conductive type; a first doping layer on a front surface of the semiconductor substrate, the first doping layer being doped with a first impurity having the first conductive type; a front surface antireflection film on the front surface of the semiconductor substrate; a back surface antireflection film on a back surface of the semiconductor substrate; an intrinsic semiconductor layer, an emitter, and a first auxiliary electrode stacked on the back surface antireflection film and the semiconductor substrate; a second doping layer on the back surface of the semiconductor substrate, the second doping layer being doped with the first impurity; an insulating film on the semiconductor substrate, the insulating film including an opening overlying the second doping layer; a second auxiliary electrode in the opening, the second auxiliary electrode overlying the second doping layer; a first electrode on the first auxiliary electrode; and a second electrode on the second auxiliary electrode, the second electrode being separated from the first electrode.

The opening in the insulating film may be smaller than a through hole in the first auxiliary electrode, the emitter, the intrinsic semiconductor layer, and the back surface antireflection film.

A flat surface pattern of the second doping layer may be equivalent to a flat surface pattern of the through hole.

The insulating film may insulate the second electrode from the first auxiliary electrode, the emitter, the intrinsic semiconductor layer, and the back surface antireflection film.

The insulating film may include a polyimide.

The solar cell may further include an oxide layer between the second doping layer and the second auxiliary electrode.

The second auxiliary electrode may include silver.

The first impurity may be an n-type impurity.

The solar cell may further include surface protrusions and depressions on at least one of the front surface and the back surface of the semiconductor substrate.

The first auxiliary electrode may include a transparent conductive oxide.

The transparent conductive oxide may include at least one of ITO, IWO, ITiO, IMO, INbO, IGdO, IZO, IZrO, AZO, BZO, GZO, and FTO.

The semiconductor substrate may include crystalline silicon.

The embodiments may also be realized by providing a method of manufacturing a solar cell, the method including providing a semiconductor substrate having a first conductive type; forming an intrinsic semiconductor layer, an emitter, and a first auxiliary electrode on the semiconductor substrate; forming a through hole by etching the first auxiliary electrode, the emitter, and the intrinsic semiconductor layer such that the through hole exposes portions of the semiconductor substrate; forming a second doping layer by doping a first impurity having the first conductive type into the portions of the semiconductor substrate exposed through the through hole; forming an insulating film in the through hole such that the insulating film includes an opening exposing the second doping layer; forming a second auxiliary electrode in the opening such that the second auxiliary electrode overlies the second doping layer; forming a first electrode on the first auxiliary electrode; and forming a second electrode on the second auxiliary electrode.

Forming the through hole and forming the second doping layer may be performed simultaneously.

Forming the through hole and forming the second doping layer may include irradiating laser beams on the semiconductor substrate as the semiconductor substrate is dipped into a solution including the first impurity.

The first auxiliary electrode may include a transparent conductive oxide.

The second auxiliary electrode may include silver.

The method may further include forming an oxide layer on the second doping layer by oxidizing the semiconductor substrate after forming the second doping layer.

Forming the first electrode and forming the second electrode may include performing a screen printing process.

### BRIEF DESCRIPTION OF THE DRAWINGS

Features will become apparent to those of ordinary skill in the art by describing in detail exemplary embodiments with reference to the attached drawings in which:

FIG. 1 illustrates a cross-sectional view of a solar cell according to an embodiment.

FIG. 2 to FIG. 7 sequentially illustrate cross-sectional views of stages in a method of manufacturing a solar cell according to an embodiment.

FIG. 8 illustrates a cross-sectional view of a solar cell according to another embodiment.

FIG. 9 illustrates a cross-sectional view of a solar cell according to yet another embodiment.

### DETAILED DESCRIPTION

Korean Patent Application No. 10-2011-0121045, filed on Nov. 18, 2011, in the Korean Intellectual Property Office, and entitled: “Solar Cell and Manufacturing Method Thereof,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. In addition, it will also be understood that when a layer is referred to as being “between” two layers, it can be the only layer between the two layers, or one or more intervening layers may also be present. Like reference numerals refer to like elements throughout.

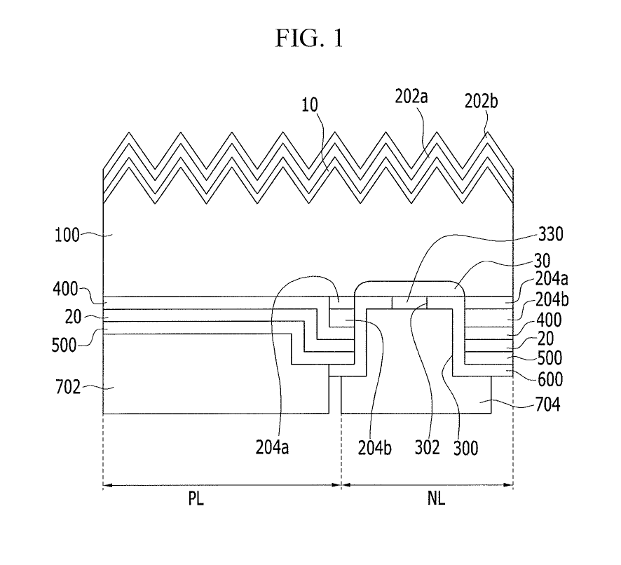

FIG. 1 illustrates a cross-sectional view of a solar cell according to an embodiment.

Referring to FIG. 1, the solar cell may include a semiconductor substrate 100. A surface of the semiconductor substrate 100 on which light is applied will be referred to as a front surface, and an opposite surface on which first and second electrodes 702, 704 are formed will be called a back surface.

The semiconductor substrate 100 may be a crystalline silicon (c-Si) wafer. The crystalline structure may include one of polycrystalline, single crystalline, and microcrystalline.

The semiconductor substrate 100 may be doped with a first impurity of a first conductive type. For example, the first conductive type may be n-type or p type. The n-type impurity may include an impurity of a pentavalent element, e.g., phosphorus (P), arsenic (As), and/or antimony (Sb). The p-type impurity includes an impurity of a trivalent element, e.g., boron (B), gallium (Ga), and/or indium (In).

A first doping layer 10 may be formed on the front surface of the semiconductor substrate 100. In an implementation, the first doping layer 10 may be formed on an entire front surface of the semiconductor substrate 100.

The first doping layer 10 may be doped with the first impurity of the first conductive type in a like manner of the semiconductor substrate 100. In an implementation, the first doping layer 10 may have a concentration of the first impurity of the first conductive type greater concentration than a concentration of the first impurity of the first conductive type of the semiconductor substrate 100.

For example, regarding the first doping layer 10, a potential barrier may be formed by a difference in the impurity concentration between the semiconductor substrate 100 and the first doping layer 10. Thus, movement of holes to the front surface of the semiconductor substrate 100 may be hindered, and the first doping layer 10 may become a front surface field (FSF) of the solar cell (for reducing recombination of the electrons and the holes near the surface of the semiconductor substrate 100 and extinction thereof).

The front surface of the semiconductor substrate 100 may have protrusions and depressions, e.g., may have a textured surface pattern. Reflectivity of the front surface may be reduced, and an amount of light that is absorbed (due to an increase in a light passing length) in the solar cell may be increased due to the protrusions and depressions on the surface. Therefore, a short circuit current of the solar cell may be improved.

Front surface antireflection films 202a and 202b may be formed on the semiconductor substrate 100. The front surface antireflection films 202a and 202b may be formed on the semiconductor substrate 100 along the protrusions and depressions.

The front surface antireflection films 202a and 202b may include a bottom antireflection film 202a (including, e.g., silicon oxide) and a top antireflection film 202b (including, e.g., silicon nitride).

More light, e.g., sunlight, may be applied by employing a refractive index difference between the front surface antireflection films 202a and 202b. The bottom antireflection film 202a may be formed to be less than about 500 Å thick, and the top antireflection film 202b may be formed to be about 100 Å to about 1,000 Å thick.

The front surface antireflection films 202a and 202b may help remove surface defects (such as a dangling bond) from the surface of the semiconductor substrate 100 and thus may help reduce and/or prevent extinction of the charges that are moved to the front surface of the semiconductor substrate 100.

Back surface antireflection films 204a and 204b may be formed on the back surface of the semiconductor substrate 100. The back surface antireflection films 204a and 204b may be formed of the same material as the front surface antireflection films 202a and 202b. For example, a bottom antireflection film 204a may include silicon oxide, and a top antireflection film 204b may include silicon nitride. The bottom antireflection film 204a may be formed to be less than about 500 Å thick, and the top antireflection film 204b may be formed to be about 100 Å to about 1,000 Å thick.

An intrinsic semiconductor layer 400, an emitter 20, and a first auxiliary electrode 500 may be formed on the back surface antireflection films 204a and 204b and the back surface of the semiconductor substrate 100.

The intrinsic semiconductor layer 400 may include, e.g., amorphous silicon. The intrinsic semiconductor layer 400 may help reduce a surface defect on the semiconductor substrate 100 to thereby improve an interface characteristic between the semiconductor substrate 100 (including, e.g., crystalline silicon) and the emitter 20. The emitter 20 may be doped with a second impurity having a second conductive type, e.g., boron (B) or a p-type conductive impurity.

The emitter 20 may represent an emitter of the solar cell, and may form a hetero junction with the semiconductor substrate 100 in addition to the p-n junction.

The first auxiliary electrode 500 may include, e.g., a transparent conductive oxide (TCO) material, and may form an ohmic contact between the emitter 20 and the first electrode 702.

The transparent conductive oxide material include, e.g., indium tin oxide (ITO), indium tungsten oxide (IWO), indium titanium oxide (ITiO), indium molybdenum oxide (IMO), indium niobium oxide (INbO), indium gadolinium oxide (IGdO), indium zinc oxide (IZO), indium zirconium oxide (IZrO), aluminum zinc oxide (AZO), boron-doped zinc oxide (BZO), gallium-doped zinc oxide (GZO), and/or fluorine-doped tin oxide (FTO).

The intrinsic semiconductor layer 400, the emitter 20, and the first auxiliary electrode 500 may have a same or similar flat surface pattern or structure.

A through hole 300 (for exposing the semiconductor substrate 100) may be formed in the first auxiliary electrode 500, the emitter 20, and the intrinsic semiconductor layer 400.

A second doping layer 30 may be formed on a portion of the semiconductor substrate 100 exposed through the through hole 300.

The second doping layer 30 may be doped with the same material as the first doping layer 10, e.g., the first impurity. The second doping layer 30 may have a doping concentration that is greater than the doping concentration of the semiconductor substrate 100. The second doping layer 30 may form an ohmic contact between the semiconductor substrate 100 and a second auxiliary electrode 330 (described in greater detail below). In a like manner of the first doping layer 10, the second doping layer 30 may become a back surface field (BSF) layer of the solar cell and may help reduce recombination and extinction of holes after they are moved to the electrode.

An insulating film 600 may be formed on an inner wall of the through hole 300 and may include, e.g., a polyimide. The insulating film 600 may include an opening 302 exposing the semiconductor substrate 100. A second auxiliary electrode 330 (contacting the second doping layer 30 and filling the opening 302) may be formed in the opening 302. The second auxiliary electrode may include, e.g., silver (Ag).

The first electrode 702 may be on the first auxiliary electrode 500, and the second electrode 704 may be on the insulating film 600 and the second auxiliary electrode 330.

The first electrode 702 may contact the first auxiliary electrode 500 and may be electrically connected thereto. The first electrode 702 may be insulated from the second electrode 704 by the insulating film 600. A boundary of the second electrode 702 may be provided in a boundary of the insulating film 600, and the second electrode 704 may fill the through hole 300 (in which the insulating film 600 is formed). The second electrode 704 may be electrically connected to the second auxiliary electrode 330.

The first electrode 702 and the second electrode 704 may be made with or may include the same material. For example, the first electrode 702 and the second electrode 704 may include any suitable conductive metal material. In an implementation, the first electrode 702 and the second electrode 704 may include at least one conductive material selected from the group of nickel (Ni), silver (Ag), aluminum (Al), tin (Sn), zinc (Zn), indium (In), titanium (Ti), copper (Cu), gold (Au), and a combination thereof.

As described above, regarding the solar cell according to the present embodiment, the semiconductor substrate 100, the intrinsic semiconductor layer 400, and the emitter 20 may form a p-i-n structure. For example, when light is absorbed in the n-type semiconductor substrate 100, carriers such as electrons and holes may be generated. The carriers may move in different directions due to an internal potential difference of the carriers according to the photovoltaic effect. The holes may move to the first electrode 702 through an emitter layer, and the electrons may move to the second electrode 704 through the semiconductor substrate 100. When the first electrode 702 and the second electrode 704 are connected to a cable, a current may be used as power for an external load or device.

In the present embodiment, the semiconductor substrate 100 may be an n-type semiconductor substrate, and the first doping layer 10 and the second doping layer 30 may be doped with an n-type impurity. For ease of description, a region where the emitter 20 is provided may be referred to as a p-type area, and another region where the second doping layer 30 is formed may be referred to as an n-type area.

The regions may be doped by using an additional mask, and may then be patterned to form the p-type area (PL) and the n-type area (NL). For example, when the emitter 20 is formed, and the second doping layer 30 is formed by using the through hole 300, the p-type and n-type dope areas may be easily formed.

When the emitter 20 is formed, and the n-type area (NL) is formed by using the through hole 300, controlling a size of the n-type area (NL) by controlling a size of the through hole 300 may be facilitated.

In an implementation, the p-type area (PL) may be larger than the n-type area (NL). Thus, current density may be increased and photo-conversion efficiency may be improved. Further, an intrinsic semiconductor may be formed in the p-type area (PL) in order to control recombination that occurs when the area of the p-type area (PL) is increased. Thus, high current density and high open voltage may be simultaneously obtained.

Further, the first electrode 702 may be insulated from the second electrode 704 by the insulating film 600. Thus, a leakage current therebetween may be reduced and/or prevented.

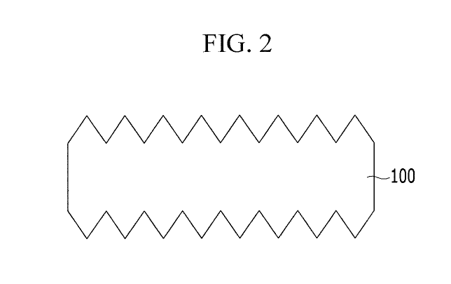

A method of manufacturing the solar cell will now be described with reference to FIG. 2 to 7.

FIG. 2 to FIG. 7 sequentially illustrate cross-sectional views of stages in a method of manufacturing a solar cell according to an embodiment.

As shown in FIG. 2, protrusions and depressions may be formed on a surface of the semiconductor substrate 100 by surface texturing the surface of the semiconductor substrate 100.

The surface texturing may include, e.g., a chemical method that includes etching the surface by using an etchant or an etching gas and/or a method of forming grooves by using laser beams or forming a pyramid by using a plurality of diamond edges.

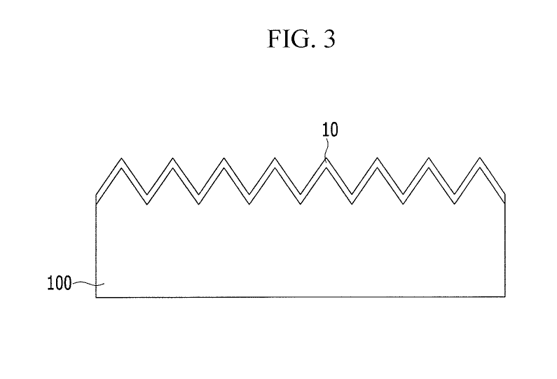

As shown in FIG. 3, the first doping layer 10 may be formed by doping the first impurity, e.g., n-type impurity, on the semiconductor substrate 100. The n-type impurity may include, e.g., phosphorus (P) and/or arsenic (As). The n-type impurity may be deactivated inside the semiconductor substrate 100 through a heat treatment.

When the n-type impurity is doped, the surface and the impurity may react to form a phosphosilicate glass (PSG) film on the surface of the semiconductor substrate 100. The PSG film may include a metal impurity extracted from an interior of the semiconductor substrate 100. Therefore, when diffusion is finished, diluted hydrofluoric acid (HF) may be used to remove the PSG film.

A side of the semiconductor substrate 100 may be flattened or planarized by a chemical polishing process that removes the protrusions and the depressions on the back surface of the semiconductor substrate 100.

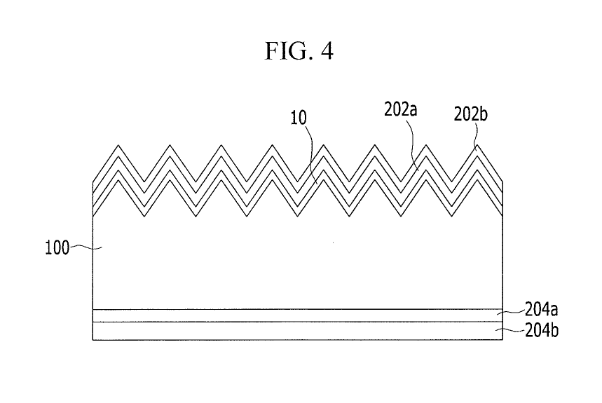

As shown in FIG. 4, the antireflection films (202a, 202b, 204a, 204b) may be formed on the front surface and the back surface of the semiconductor substrate 100.

The bottom antireflection films 202a and 204a may be formed by thermally oxidizing the semiconductor substrate 100. The bottom antireflection films 202a and 204a may be formed to be less than about 300 Å thick. The top antireflection films 202b and 204b may be formed of, e.g., silicon nitride by using, e.g., a low pressure CVD (LPCVD) process. Hydrogen included in the antireflection films 202a, 202b, 204a, 204b may help increase a lifetime of carriers by reducing defects on the surface of the semiconductor substrate 100.

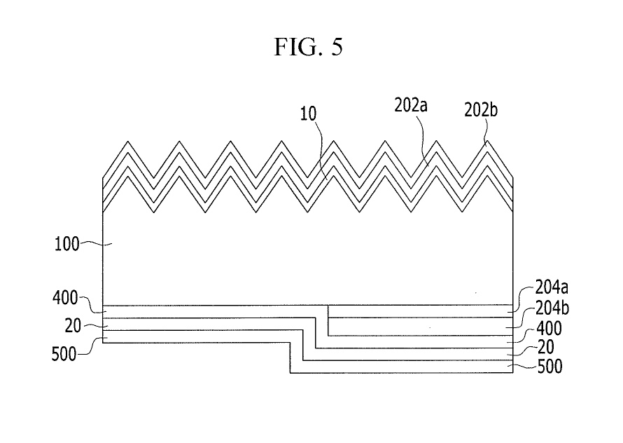

As shown in FIG. 5, a portion of the back surface antireflection films 204a and 204b of the semiconductor substrate 100 may be removed by, e.g., using an etching paste. For example, portions of the back surface antireflection films 204a and 204b in the p-type area may be removed so as to facilitate formation of a pn junction between the emitter 20 and the semiconductor substrate 100.

The intrinsic semiconductor layer 400, the emitter 20, and the first auxiliary electrode 500 may be stacked to cover the back surface antireflection films 204a and 204b and the semiconductor substrate 100. The emitter 20 may be formed with a p-type semiconductor.

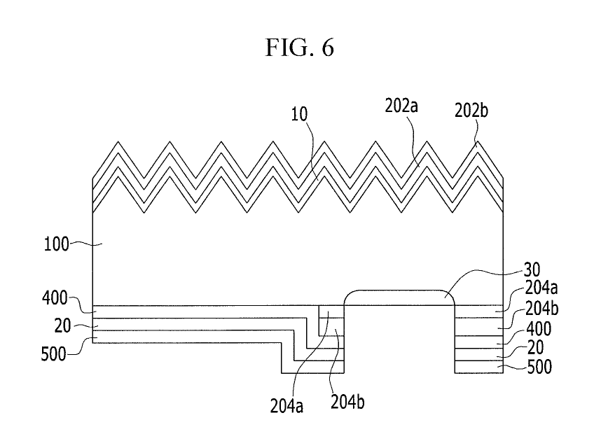

As shown in FIG. 6, portions of the back surface antireflection films 204a and 204b, the first auxiliary electrode 500, the emitter 20, and the intrinsic semiconductor layer 400 may be removed by, e.g., laser beams, thereby forming the through hole 300 exposing the semiconductor substrate 100. The second doping layer 30 may be formed on portions of the semiconductor substrate 100 exposed through the through hole 300.

For example, the semiconductor substrate 100 may be dipped into a solution including ions or impurities (for doping into the second doping layer 30) and the laser beams may be irradiated thereon. Thus, the through hole 300 may be formed, and the ions or impurities may be simultaneously doped into the semiconductor substrate 100 to form the second doping layer 30.

For example, the laser beams may be irradiated onto the semiconductor substrate 100 in a phosphoric acid solution. Thus, the ions may be doped into the second doping layer 30 as an n-type impurity. In an implementation, the impurity concentration of the second doping layer 30 may be controlled by a concentration of the phosphoric acid solution and irradiation of the laser beams.

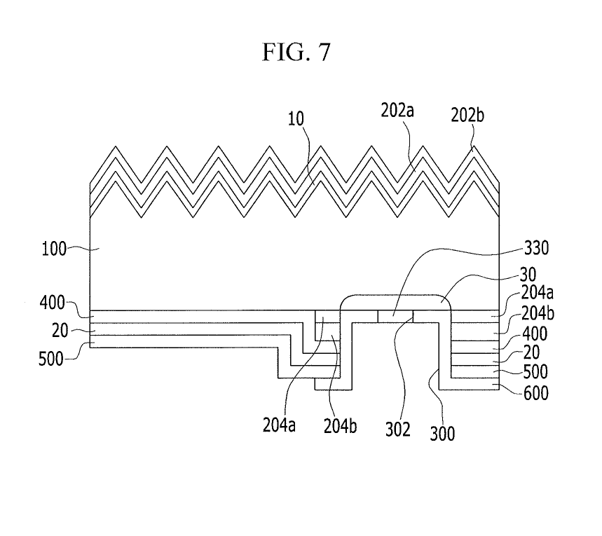

As shown in FIG. 7, the insulating film 600 (having the opening 302) may be formed in the through hole 300 by, e.g., a screen printing method. In an implementation, any suitable materials for screen printing may be used to form the insulating film 600. For example, the insulating film 600 may include a polyimide.

The second auxiliary electrode 330 (for filling the opening 302) may be formed by a light induced plating (LIP) process. Any suitable metal available for plating may be used to form the second auxiliary electrode 330. For example, the second auxiliary electrode 330 may include silver (Ag).

As shown in FIG. 1, the first electrode 702 and the second electrode 704 may then be formed by a screen printing process. The first electrode 702 and the second electrode 704 may be formed to be, e.g., single or double layers, including, e.g., titanium, tungsten, and/or copper.

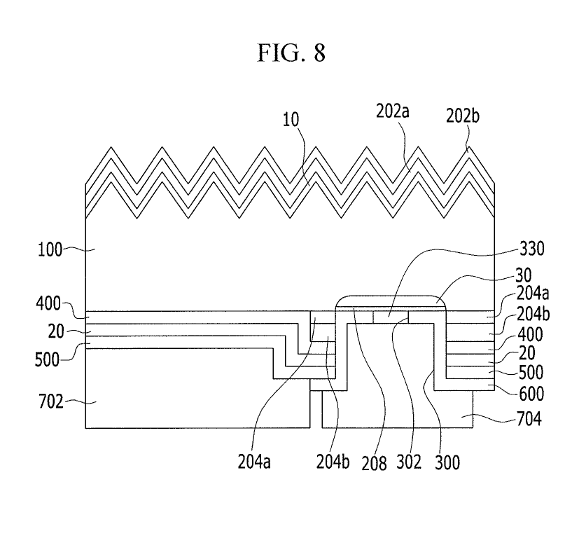

FIG. 8 illustrates a cross-sectional view of a solar cell according to another embodiment.

The configuration of the solar cell shown in FIG. 8 may generally be equivalent to that of the solar cell of FIG. 1, and a repeated description thereof may be omitted.

The solar cell according to the present embodiment may further include an oxide layer 208 on the second doping layer 30. As shown in FIG. 8, the oxide layer 208 may be formed when the second doping layer 30 is formed. For example, the semiconductor substrate 100 may be dipped into ozone water or a peroxide solution. In an implementation, a passivation effect (for reducing a surface defect of the semiconductor substrate 100) may be expected by hydrogen of the oxide layer. It may be desirable to form the oxide layer to be less than about 100 Å thick.

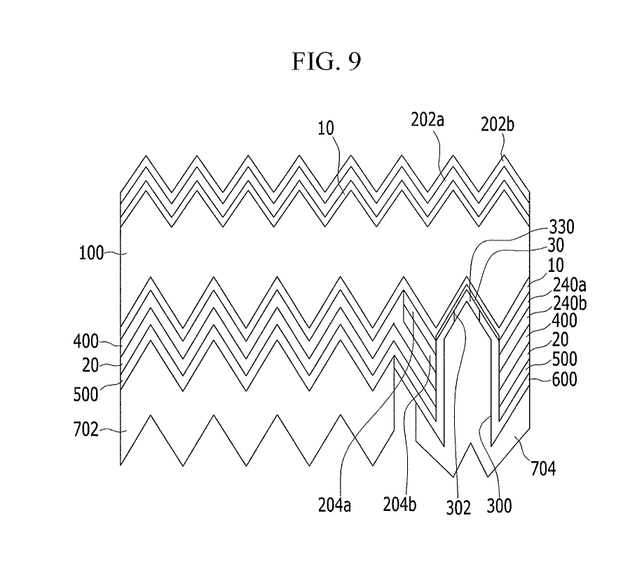

FIG. 9 illustrates a cross-sectional view of a solar cell according to yet another embodiment.

The configuration of the solar cell shown in FIG. 9 may generally be equivalent to the solar cell of FIG. 1, and a repeated description thereof may be omitted.

Regarding the solar cell according to the present embodiment, surface protrusions and depressions may be formed on the front surface and the back surface of the semiconductor substrate 100.

In the solar cell shown in FIG. 1, the PSG film may be removed and the protrusions and the depressions on the back surface of the semiconductor substrate 100 may be planarized through a chemical polishing process. Further, an antireflection film may be formed after the PSG film is removed. However, in the present embodiment, the process for removing the back surface protrusions and depressions may be omitted, and the method of manufacturing the solar cell may be simplified.

The embodiments provide a high-efficiency back-surface electrode type of solar cell and a manufacturing method thereof.

The solar cell according to the embodiment may help minimize light absorption on the front surface protection film by using silicon oxide and silicon nitride.

Further, the solar cell may form the p-type amorphous silicon film and may then form the n-type doping layer by using the through hole to increase the p-type area, increase current density, and improve photo-conversion efficiency.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A solar cell, comprising:
a crystalline semiconductor substrate having a first conductive type;
a first doping layer on a front surface of the semiconductor substrate, the first doping layer being doped with a first impurity having the first conductive type;
a front surface antireflection film on the front surface of the semiconductor substrate;
a back surface antireflection film on a back surface of the semiconductor substrate;
an intrinsic semiconductor layer, an emitter, and a first auxiliary electrode stacked on the back surface antireflection film and the semiconductor substrate;
a second doping layer on the back surface of the semiconductor substrate, the second doping layer being doped with the first impurity;
an insulating film on the semiconductor substrate, the insulating film including an opening overlying the second doping layer;
a second auxiliary electrode in the opening, the second auxiliary electrode overlying the second doping layer;
a first electrode on the first auxiliary electrode; and
a second electrode on the second auxiliary electrode, the second electrode being separated from the first electrode.

2. The solar cell as claimed in claim 1, wherein the opening in the insulating film is smaller than a through hole in the first auxiliary electrode, the emitter, the intrinsic semiconductor layer, and the back surface antireflection film.

3. The solar cell as claimed in claim 2, wherein a flat surface pattern of the second doping layer is equivalent to a flat surface pattern of the through hole.

4. The solar cell as claimed in claim 2, wherein the insulating film insulates the second electrode from the first auxiliary electrode, the emitter, the intrinsic semiconductor layer, and the back surface antireflection film.

5. The solar cell as claimed in claim 2, wherein the insulating film includes a polyimide.

6. The solar cell as claimed in claim 1, further comprising an oxide layer between the second doping layer and the second auxiliary electrode.

7. The solar cell as claimed in claim 1, wherein the second auxiliary electrode includes silver.

8. The solar cell as claimed in claim 1, wherein the first impurity is an n-type impurity.

9. The solar cell as claimed in claim 1, further comprising surface protrusions and depressions on at least one of the front surface and the back surface of the semiconductor substrate.

10. The solar cell as claimed in claim 1, wherein the first auxiliary electrode includes a transparent conductive oxide.

11. The solar cell as claimed in claim 10, wherein the transparent conductive oxide includes at least one of ITO, IWO, ITiO, IMO, INbO, IGdO, IZO, IZrO, AZO, BZO, GZO, and FTO.

12. The solar cell as claimed in claim 1, wherein the semiconductor substrate includes crystalline silicon.

13. A method of manufacturing a solar cell, the method comprising:
providing a semiconductor substrate having a first conductive type;
forming an intrinsic semiconductor layer, an emitter, and a first auxiliary electrode on the semiconductor substrate;
forming a through hole by etching the first auxiliary electrode, the emitter, and the intrinsic semiconductor layer such that the through hole exposes portions of the semiconductor substrate;
forming a second doping layer by doping a first impurity having the first conductive type into the portions of the semiconductor substrate exposed through the through hole;
forming an insulating film in the through hole such that the insulating film includes an opening exposing the second doping layer;
forming a second auxiliary electrode in the opening such that the second auxiliary electrode overlies the second doping layer;
forming a first electrode on the first auxiliary electrode; and
forming a second electrode on the second auxiliary electrode.

14. The method as claimed in claim 13, wherein forming the through hole and forming the second doping layer are performed simultaneously.

15. The method as claimed in claim 14, wherein forming the through hole and forming the second doping layer include irradiating laser beams on the semiconductor substrate as the semiconductor substrate is dipped into a solution including the first impurity.

16. The method as claimed in claim 14, wherein the first auxiliary electrode includes a transparent conductive oxide.

17. The method as claimed in claim 14, wherein the second auxiliary electrode includes silver.

18. The method as claimed in claim 14, further comprising forming an oxide layer on the second doping layer by oxidizing the semiconductor substrate after forming the second doping layer.

19. The method as claimed in claim 18, wherein forming the first electrode and forming the second electrode include performing a screen printing process.
